(19) United States
(12) Patent Application Publication
(10) Pub. No.: US 2007/0202614 A1
(43) Pub. Date: Aug. 30, 2007

(54) METHOD AND APPARATUS FOR COMBINATORIALLY VARYING MATERIALS, UNIT PROCESS AND PROCESS SEQUENCE

(76) Inventors: Tony P. Chiang, San Jose, CA (US); David E. Lazovsky, San Jose, CA (US); Kurt Weiner, San Jose, CA (US); Gustavo Pinto, San Jose, CA (US); Thomas Boussie, San Jose, CA (US); Alexander Gorer, San Jose, CA (US)

Correspondence Address: MARTINE PENILLA GENCARELLA, LLP, 710 LAKEWAY DRIVE, SUITE 200, SUNNYVALE, CA, 94085, US

(21) Appl. No.: 11/674,132

(22) Filed: Feb. 12, 2007

Related U.S. Application Data
(63) Continuation-in-part of application No. 11/352,077, filed on Feb. 10, 2006.
(63) Continuation-in-part of application No. 11/419,174, filed on May 18, 2006.

(51) Int. Cl. H01L 21/66

(52) U.S. Cl. 438/14

(57) ABSTRACT

A method for analyzing and optimizing fabrication techniques using variations of materials, unit processes, and process sequences is provided. In the method, a subset of a semiconductor manufacturing process sequence and build is analyzed for optimization. During the execution of the subset of the manufacturing process sequence, the materials, unit processes, and process sequence for creating a certain structure is varied. During the combinatorial processing, the materials, unit processes, or process sequence is varied between the discrete regions of a semiconductor substrate, wherein within each of the regions the process yields a substantially uniform or consistent result that is representative of a result of a commercial manufacturing operation. A tool for optimizing a process sequence is also provided.

### CLAIM OF PRIORITY

This application is a continuation-in-part and claims the benefit of U.S. application Ser. No. 11/352,077 filed Feb. 10, 2006, and U.S. application Ser. No. 11/419,174 filed May 18, 2006, which are incorporated by reference in their entirely for all purposes. This application is related to U.S. application Ser. No. (Atty Docket INTMP003B) filed on the same day as the present application and entitled “Method and Apparatus for Combinatorially Varying Materials, Unit Process and Process Sequence.”

### BACKGROUND

The manufacturing of integrated circuits (IC) semiconductor devices, flat panel displays, optoelectronics devices, data storage devices, magneto electronic devices, magneto optic devices, packaged devices, and the like entails the integration and sequencing of many unit processing steps. For example, IC manufacturing typically includes a series of processing steps such as cleaning, surface preparation, deposition, lithography, patterning, etching, planarization, implantation, thermal annealing and other related unit processing steps. The precise sequencing and integration of the unit processing steps enable the formation of functional devices meeting desired performance specifications such as speed, power consumption, yield and reliability. Furthermore, the tools and equipment employed in device manufacturing have been developed to enable the processing of ever increasing substrate sizes such as the move to twelve inch (or 300 millimeter) diameter wafers in order to fit more ICs per substrate per unit processing step for productivity and cost benefits. Other methods of increasing productivity and decreasing manufacturing costs include the use of batch reactors whereby multiple monolithic substrates can be processed in parallel. In these processing steps a monolithic substrate or batch of monolithic substrates are processed uniformly, i.e., in the same fashion with the same resulting physical, chemical, electrical, and the like properties across a given monolithic substrate.

The ability to process uniformly across a monolithic substrate and/or across a series of monolithic substrates is advantageous for manufacturing efficiency and cost effectiveness, as well as repeatability and control. However, uniform processing across an entire substrate can be disadvantageous when optimizing, qualifying or investigating new materials, new processes, and/or new process sequence integration schemes, since the entire substrate is nominally made the same using the same materials, processes and process sequence integration scheme. Each so processed substrate represents in essence only one possible variation per substrate. Thus, the full wafer uniform processing under conventional processing techniques results in fewer data points per substrate, longer times to accumulate a wide variety of data and higher costs associated with obtaining such data.

Accordingly, there is a need to be able to more efficiently screen and analyze an array of materials, processes, and process sequence integration schemes across a substrate in order to more efficiently evaluate alternative materials, processes, and process sequence integration schemes for semiconductor manufacturing processes.

### SUMMARY

Embodiments of the present invention provide a method and a system for screening a semiconductor manufacturing operation having numerous possible materials, processes and process sequences to derive an optimum manufacturing method or integration sequence, or a relatively small set of optimum manufacturing methods. Several inventive embodiments of the present invention are described below.

In one aspect of the invention, a method for analyzing and optimizing semiconductor fabrication techniques using variations of materials, unit processes, and process sequences is provided. In the method, a subset of a semiconductor manufacturing process sequence and build is analyzed for optimization. During the execution of the subset of the manufacturing process sequence, the materials, unit processes, and process sequence for creating a certain structure is varied. For example, adhesion layers in interconnect applications could be analyzed through a combination of blanket depositions and combinatorial variations in discrete regions on the substrate. During the combinatorial processing, the materials, unit processes, or process sequence is varied between the discrete regions of a semiconductor substrate, wherein within each of the regions the process yields a substantially uniform or consistent result that is representative of a result of a commercial semiconductor manufacturing operation. Moreover, the variation is introduced in a controlled manner, so that testing will determine any differences due to the variation without having to be concerned with external factors causing testing anomalies.

In one embodiment, primary, secondary and tertiary screening levels are defined during the combinatorial process sequence in order to methodically optimize the materials, unit processes, and process sequence of the semiconductor manufacturing operation. In another embodiment, a structure, series of structures or partial structure(s) in each region is tested for physical, chemical, electrical, magnetic, etc., properties during the screening. Based on the results of this testing further screening is performed where the materials, unit processes, and process sequences having the desired characteristics are included, while other materials, processes, and process sequences not having the desired characteristics are eliminated. Once a portion of the materials, unit processes, and process sequences having the desired characteristics are identified, then those aspects can be performed in a conventional manner, i.e., non-combinatorially, and other aspects of the materials, unit processes, or process sequence can be varied combinatorially. The iterative repeating of this process eventually yields an optimized semiconductor manufacturing process sequence, which takes into account the interaction of the process and the process sequence as opposed to a material-centric viewpoint.

In another aspect of the invention, a tool for optimizing a process sequence for manufacturing a production wafer that may contain devices defined thereon is provided. In one embodiment, the production wafer is at least 6 inches in diameter, however, the production wafer can be any suitable size or shape that includes diameters less than or greater than 6 inches. The tool includes a mainframe having a plurality of modules attached thereto. One of the modules is a combinatorial processing module. Through the combinatorial module, an order of the process sequence, unit processes, process conditions, and/or materials are varied among regions of the wafer being processed. In one embodiment, the mainframe includes a combinatorial processing module and a conventional processing module. The modules are configured to define structures on a semiconductor substrate according to a process sequence order. One or more processes of the process sequence order are performed in the combinatorial processing module. The process or processes performed in the combinatorial module is varied in discrete regions of the semiconductor substrate through the combinatorial processing module.

Other aspects of the invention will become apparent from the following detailed description, taken in conjunction with the accompanying drawings, illustrating by way of example the principles of the invention.

### BRIEF DESCRIPTION OF THE DRAWINGS

The present invention will be readily understood by the following detailed description in conjunction with the accompanying drawings. Like reference numerals designate like structural elements.

FIG. 1 is a simplified schematic diagram illustrating a general methodology for combinatorial process sequence integration that includes site isolated processing and/or conventional processing in accordance with one embodiment of the invention.

FIGS. 2A-C are simplified schematic diagrams illustrating isolated and slightly overlapping regions in accordance with one embodiment of the invention.

FIG. 3 is a simplified schematic diagram illustrating the testing hierarchy for a screening process in accordance with one embodiment of the invention.

FIG. 4 is a simplified schematic diagram illustrating an overview of the screening process for use in evaluating materials, processes, and process sequences for the manufacturing of semiconductor devices in accordance with one embodiment of the invention.

FIGS. 5A and 5B are a simplified schematic diagrams illustrating integrated high productivity combinatorial (HPC) systems in accordance with one embodiment of the invention.

FIG. 6 is a flow chart diagram illustrating the method operations for selecting an optimized process sequence for a semiconductor manufacturing process in accordance with one embodiment of the invention.

FIG. 7 is a simplified schematic diagram illustrating a specific example for integrating a combinatorial process with conventional processing in order to evaluate process sequence integration that includes site isolated processing in accordance with one embodiment of the invention.

FIGS. 8A and 8B illustrate exemplary workflows of the screening process described herein as applied to a copper capping layer in accordance with one embodiment of the invention.

FIGS. 9A-9C illustrates the application of the screening process to a process sequence for a gate stack configuration in accordance with one embodiment of the invention.

FIGS. 10A and 10B illustrate an exemplary screening technique for evaluating a metal-insulator-metal (MIM) structure for a memory device in accordance with one embodiment of the invention.

FIG. 11 illustrates a simplified cross sectional view of a substrate that has structures defined from combinatorial processing sequences for screening purposes in accordance with one embodiment of the invention.

### DETAILED DESCRIPTION

The embodiments described herein provide a method and system for evaluating materials, unit processes, and process integration sequences to improve semiconductor manufacturing operations. It will be obvious, however, to one skilled in the art, that the present invention may be practiced without some or all of these specific details. In other instances, well known process operations have not been described in detail in order not to unnecessarily obscure the present invention.

The embodiments described herein enable the application of combinatorial techniques to process sequence integration in order to arrive at a globally optimal sequence of semiconductor manufacturing operations by considering interaction effects between the unit manufacturing operations, the process conditions used to effect such unit manufacturing operations, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a semiconductor device. A global optimum sequence order is therefore derived and as part of this derivation, the unit processes, unit process parameters and materials used in the unit process operations of the optimum sequence order are also considered.

The embodiments described further below analyze a portion or sub-set of the overall process sequence used to manufacture a semiconductor device. Once the subset of the process sequence is identified for analysis, combinatorial process sequence integration testing is performed to optimize the materials, unit processes and process sequence used to build that portion of the device or structure. During the processing of some embodiments described herein, structures are formed on the processed semiconductor substrate that are equivalent to the structures formed during actual production of the semiconductor device. For example, such structures may include, but would not be limited to, trenches, vias, interconnect lines, capping layers, masking layers, diodes, memory elements, gate stacks, transistors, or any other series of layers or unit processes that create an intermediate structure found on semiconductor chips. While the combinatorial processing varies certain materials, unit processes, or process sequences, the composition or thickness of the layers or structures or the action of the unit process, such as cleaning, surface preparation, etch, deposition, planarization, implantation, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or one of various process parameters may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, or process sequences) and not the lack of process uniformity. In contrast, gradient processing techniques require variation across layers and non-uniformity within layers occurs so that a rapid scan of various material compositions is obtained. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed. Gradient processing techniques are unable to deliver the uniformity or consistency at arbitrary locations to build structures from a commercial semiconductor chip or enable statistical analysis of the impact of varying the materials, unit processes or process sequences between various areas of the substrate. That is, the output of a gradient processing operation is customized for a particular testing purpose and this output is unable to provide any data with regard to process sequence interactions, as the gradient processes are not easily translatable to many processes used during the commercial creation of a semiconductor device.

While the gradient technique has the above limitations, it does enable a rapid scan of material properties and may be incorporated into the front end of the techniques described herein to identify possible material candidates to be incorporated into the combinatorial process sequence integration being analyzed and optimized. However, due to the inherent variation and non-uniformity within a location, the gradient processing techniques are unable to be used in the evaluation of process sequence integration techniques.

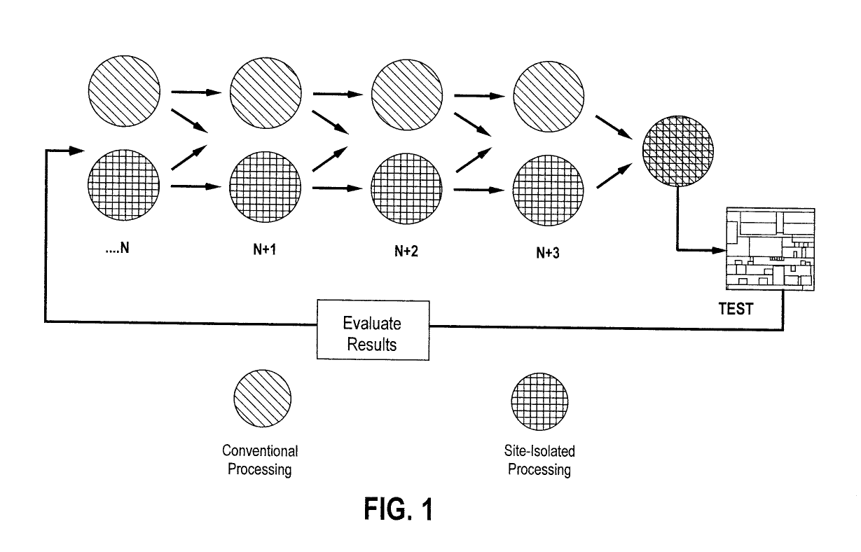

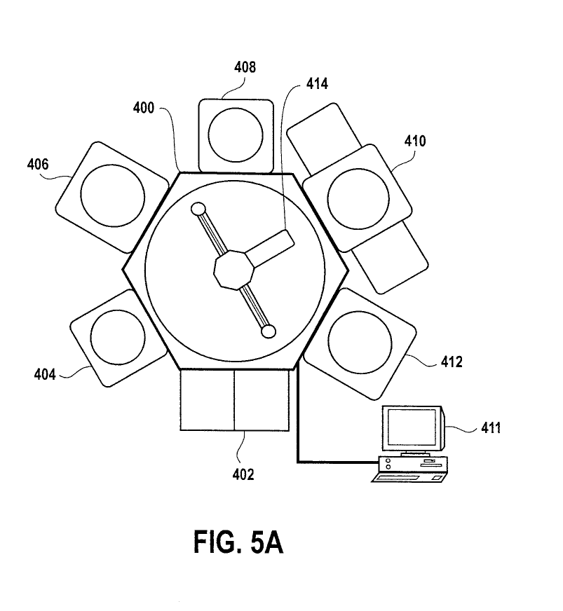

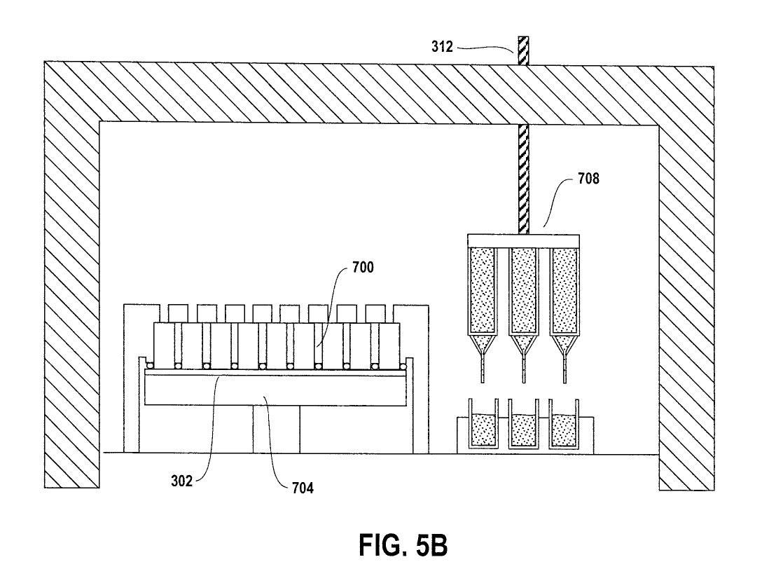

FIG. 1 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, a high productivity combinatorial (HPC) module may be used, such as the HPC module described in U.S. patent application Ser. Nos. 11/672,473 or 11/352,077, which are described further in FIGS. 5A and 5B of the present application. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 1. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, e.g. wafers as shown or portions of monolithic substrates such as coupons or wafer coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, etc. It should be appreciated that these process parameters are exemplary and not meant to be an exhaustive list as other process parameters commonly used in semiconductor manufacturing may be varied.

As mentioned above, within a region the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

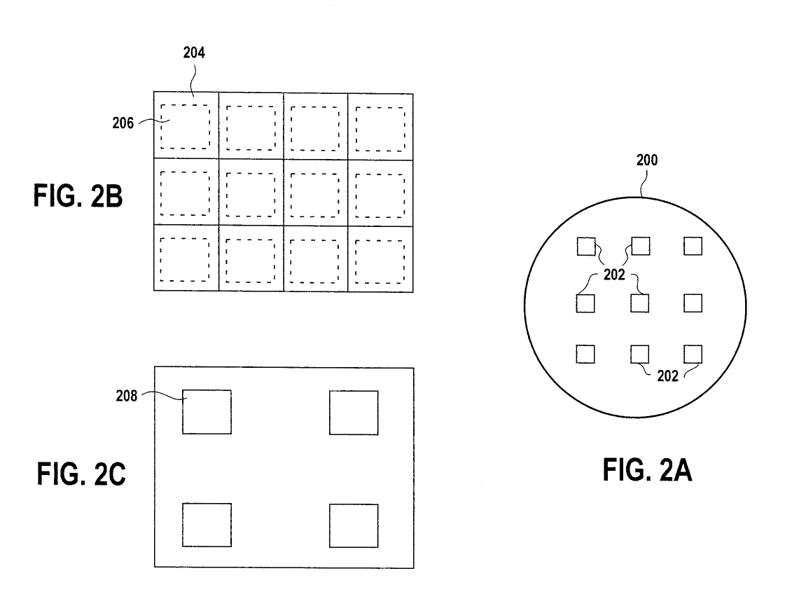

FIGS. 2A-C are simplified schematic diagrams illustrating isolated and slightly overlapping regions in accordance with one embodiment of the invention. In FIG. 2A, wafer 200 is illustrated having multiple regions 202, which generally contain multiple dies or structures. It should be appreciated that while wafer 200 is illustrated, the regions discussed herein may be disposed on a coupon or some portion of a wafer. FIG. 2B illustrates regions 204. Each instance of regions 204 shares a border with another of the regions. Within each region 204, a substantial portion 206 of the region is uniform, e.g., at least 50% or more of the region, and the desired testing can be performed within portion 206. One skilled in the art will appreciate that the shadowing between the regions 204 may occur when masks are used for the unit processing operations. However, this phenomenon does not impact the ability to produce and test the substantial portion 206 of the region, which has the desired uniform and consistent characteristics.

FIG. 2C illustrates an exemplary region having several die. In general regions will contain more than one die, but the system or series of experiments can be set up so that each region contains one die or a portion of a die, if applicable. In one embodiment, the wet processing tool described with reference to FIG. 5B is capable of providing isolated regions as illustrated in FIG. 2C. It should be appreciated that the tools defined herein enable spatial variation of features across layers. While FIGS. 2A-C may be interpreted as defining regions, this is not meant to be limiting. The region may be defined by the design of experiment, tooling or other site isolated processing techniques as required for the technology at issue, which include, manufacturing of integrated circuits (IC) semiconductor devices, flat panel displays, optoelectronics devices, data storage devices, magneto electronic devices, magneto optic devices, packaged devices, and the like. As described above, regardless of the size of the region and the regions correlation to the die size, the regions may be slightly overlapping or isolated without impacting the screening technique described herein.

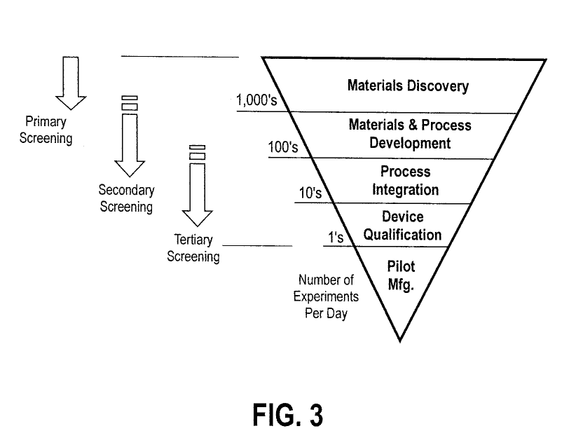

FIG. 3 is a simplified schematic diagram illustrating an overview of the High-Productivity Combinatorial (HPC) screening process for use in evaluating materials, unit processes, and process sequences for the manufacturing of semiconductor devices in accordance with one embodiment of the invention. As illustrated in FIG. 3, primary screening incorporates and focuses on materials discovery. Here, the materials may be screened for certain properties in order to select possible candidates for a next level of screening. In the initial primary screening there may be thousands of candidates which are subsequently reduced to hundreds of candidates. These hundreds of candidates can then be used or advanced to secondary screening processes which will look at materials and unit processes development. In the secondary screening level, process integration may be additionally considered to narrow the candidates from hundreds of candidates to tens of candidates. Thereafter, tertiary screening further narrows these candidates through process integration and device qualification in order to identify some best possible optimizations in terms of materials, unit processes and process sequence integration.

In one embodiment, the primary and secondary testing may occur on a coupon, while the tertiary testing is performed on a production size wafer. Through this multi-level screening process, the best possible candidates have been identified from many thousands of options. The time required to perform this type of screening will vary, however, the efficiencies gained through the HPC methods provide a much faster development system than any conventional technique or scheme. While these stages are defined as primary second and tertiary, these are arbitrary labels placed on these steps. Furthermore, primary screening is not necessarily limited to materials research and can be focused on unit processes or process sequences, but generally involves a simpler substrate, less steps and quicker testing than the later screening levels.

The stages also may overlap and there may be feedback from the secondary to the primary, and the tertiary to the secondary and/or the primary to further optimize the selection of materials, unit processes and process sequences. In this manner, the secondary screening begins while primary screening is still being completed, and/or while additional primary screening candidates are generated, and tertiary screening can begin once a reasonable set of options are identified from the secondary screening. Thus, the screening operations can be pipelined in one embodiment. As a general matter and as discussed elsewhere in more detail, the level of sophistication of the structures, process sequences, and testing increases with each level of screening. Furthermore, once the set of materials, unit processes and process sequences are identified through tertiary screening, they must be integrated into the overall manufacturing process and qualified for production, which can be viewed as quaternary screening or production qualification. In one more level of abstraction, a wafer can be pulled from the production process, combinatorially processed, and returned to the production process under tertiary and/or quaternary screening.

In the various screening levels, the process tools may be the same or may be different. For example, in dry processing the primary screening tool may be a combinatorial sputtering tool available described, for example, in U.S. Pat. No. 5,985,356. This tool is efficient at preparing multi-material samples in regions for simple materials properties analysis. For secondary and/or tertiary screening technique, a modified cluster tool may be retrofitted with a combinatorial chamber as described in FIG. 5A. As another example, in wet processing, the primary and secondary screening can be implemented in the combinatorial tool described in FIG. 5B. The main differences here are not the capabilities of the tools, but the substrates used, the process variations or structures created and the testing done. For the tertiary tool, a wet reactor with combinatorial and non-combinatorial chambers described in U.S. application Ser. No. 11/647,881 filed Dec. 29, 2006, could be used for integrated and more sophisticated processing and analysis.

In the development or screening cycle, typically there are many materials synthesized or processed involving large permutations of a plurality of materials, a plurality of processes, a plurality of processing conditions, a plurality of material application sequences, a plurality of process integration sequences, and combinations thereof. Testing of these many materials may use a simple test, such as adhesion or resistivity and may involve a blanket wafer (or coupon) or one with basic test structures to enable testing for one or more desired properties of each material or unit process. Once the successful materials or unit processes have been selected, combinatorial techniques are applied to analyze these materials or processes within a larger picture. That is, the combinatorial techniques determine whether the selected materials or unit processes meet more stringent requirements during second stage testing. The processing and testing during the second stage may be more complex, e.g., using a patterned wafer or coupon, with more test structures, larger regions, more variations, more sophisticated testing, etc. For example, the structure defined by the material and unit process sequence can be tested for properties related or derived from the structure to be integrated into the commercial product.

This iterative process may continue with larger and more complex test circuits being used for testing different parameters. This approach serves to increase the productivity of the combinatorial screening process by maximizing the effective use of the substrate real estate, and optimizing the corresponding reactor and test circuit design with the level of sophistication required to answer the level of questions necessary per stage of screening. Complex reactors and/or test circuit designs are utilized at later stages of screening when desired properties of the materials, processing conditions, process sequence, etc. are substantially known and/or have been refined via prior stages of screening.

The subsections of test structures generated from previous testing for some screening levels may be incorporated into subsequent, more complex screening levels in order to further evaluate the effectiveness of process sequence integrations and to provide a check and correlation vehicle to the previous screen. It should be appreciated that this ability allows a developer to see how results of the subsequent process differed from the results of the previous process, i.e., take into account process interactions. In one example, materials compatibility may be used as a primary test vehicle in primary screening, then specific structures incorporating those materials (carried forward from the primary screen) are used for the secondary screening. As mentioned herein, the results of the secondary screening may be fed back into the primary screening also. Then, the number and variety of test structures is increased in tertiary screening along with the types of testing, for example, electrical testing may be added or device characterization may be tested to determine whether certain critical parameters are met. Of course, electrical testing is not reserved for tertiary testing as electrical testing may be performed at other screening stages. The critical parameters generally focus on the requirements necessary to integrate the structures created from the materials and process sequence into the commercial product, e.g., a semiconductor die.

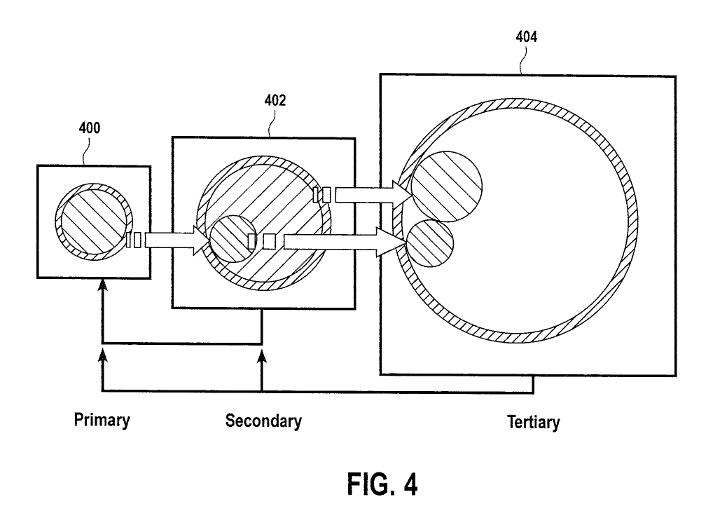

FIG. 4 is a simplified schematic diagram illustrating the testing hierarchy for a screening process in accordance with one embodiment of the invention. In an initial (primary level) test for testing some basic properties, relatively simple and small test structures are formed on the first substrate 400, which may alternatively be a blanket substrate (or multiple blanket substrates of different materials). Generally, the different regions will all have the same test structures, if applicable, but are not required to do so. In one embodiment, structures are located in the same position within each region to facilitate testing. After the reaction sequence is completed (or at various stages within the process sequence), the results are tested using the test structure and the results are screened for the next level of screening. More complex test structures are then used in regions in a second substrate 402 for a secondary level of processing and testing. The test structure from the primary level test may be incorporated along with a more complex test structure in one or more regions of the secondary level. That is, the structures on the second substrate 402 for the secondary level may be cumulative to the test structure of the first substrate for the primary level in one embodiment. Consequently, the results from both test structures may be obtained in the secondary level. The results from the test structures from the primary level can then be compared to the test results from the secondary level, to establish correlation and obtain information to determine the efficacy of the simpler primary screen. If poor correlation results, the screening metrics of the primary screen are then adjusted so as to obtain good correlation to the more sophisticated secondary level screening results. In this fashion, the primary screen can be used as a fast and simpler means of screening out those candidates who would have failed the more sophisticated and time consuming secondary level testing. This allows a wider phase space to be examined in a more efficient manner at the primary level.

Still referring to FIG. 4, the same concept is applied to a tertiary level, where the testing and screening increases in complexity, requiring more complex and larger test structures, and larger reactor areas on a third substrate 404. It should be appreciated that the test structures from the primary and secondary levels may be incorporated into the third substrate 404 so that the results provide yet another level for the analysis of the primary and secondary structures within the third level of testing. As illustrated in FIG. 4, the results may be fed back into each of the downstream processes to further enhance the screening, as the screening levels may be performed concurrently in some instances. The screening metrics for the secondary level screening are adjusted to ensure good correlation to the tertiary screening results. This allows the use of the secondary screen to address a larger phase space in a more efficient manner. In combination, the primary, secondary, and tertiary screening form a screening funnel.

One manner of looking at the difference between the primary, secondary, and tertiary levels, aside from the data sophistication and the data quality, is that the primary level tends to have more variation per unit area of substrate than the secondary and tertiary levels (i.e., the regions are smaller in the primary screen). In some embodiments, the primary and secondary variation per unit area may be the same or similar with variation between the primary and the secondary levels being defined by the structures on the substrate or the structures (or partial structures) formed through the process sequence. It should be appreciated that when performing the screening described in FIG. 4 the overall scheme shown in FIG. 1 can be used to incorporate combinatorial and conventional processing of wafers or coupons.

FIG. 5A is a simplified schematic diagram illustrating an integrated high productivity combinatorial (HPC) system in accordance with one embodiment of the invention. HPC system includes a frame 400 supporting a plurality of processing modules. It should be appreciated that frame 400 may be a unitary frame in accordance with one embodiment. In one embodiment, the environment within frame 400 is controlled. Load lock/factory interface 402 provides access into the plurality of modules of the HPC system. Robot 414 provides for the movement of substrates (and masks) between the modules and for the movement into and out of the load lock 402. Module 404 may be an orientation/degassing module in accordance with one embodiment. Module 406 may be a clean module, either plasma or non-plasma based, in accordance with one embodiment of the invention.

Module 408 is referred to as a library module in accordance with one embodiment of the invention. In module 408, a plurality of masks, also referred to as processing masks, are stored. The masks may be used in the dry combinatorial processing modules in order to apply a certain pattern to a substrate being processed in those modules. Module 410 includes a HPC physical vapor deposition module in accordance with one embodiment of the invention. Module 412 is a conventional deposition module in accordance with one embodiment of the invention. In one embodiment, a centralized controller, i.e., computing device 411, may control the processes of the HPC system. Further details of the HPC system are described in U.S. application Ser. Nos. 11/672,478, and 11/672,473.

FIG. 5B illustrates a combinatorial module configured for wet processing operation that may be used to perform the screening processes in accordance with one embodiment of the invention. Cell array 700 is brought into contact with substrate 302 Elastomeric seals are used to define discrete region on the substrate so that wet processing operation may be performed without any interference from processing being performed in any of the other regions. Dispensers 708 mounted on support arm 312 are used to deliver wet processing agents to the discrete regions. Further details of the wet combinatorial module are disclosed in U.S. application Ser. No. 11/352,077.

In one embodiment, the combinatorial module, either for wet processing or dry processing, is capable of executing techniques, methodologies, processes, test vehicles, synthetic procedures, technology, or combinations thereof used for the simultaneous, parallel, or rapid serial: (i) design, (ii) synthesis, (iii) processing, (iv) process sequencing, (v) process integration, (vi) device integration, (vii) analysis, or (viii) characterization of more than two (2) compounds, compositions, mixtures, processes, or synthesis conditions, or the structures derived from such. It should be appreciated that test vehicles include, but are not limited to, physical, electrical, photolytic, and/or magnetic characterization devices such as test structures or chips, used in the design, process development, manufacturing process qualification, and manufacturing process control of integrated circuit devices.

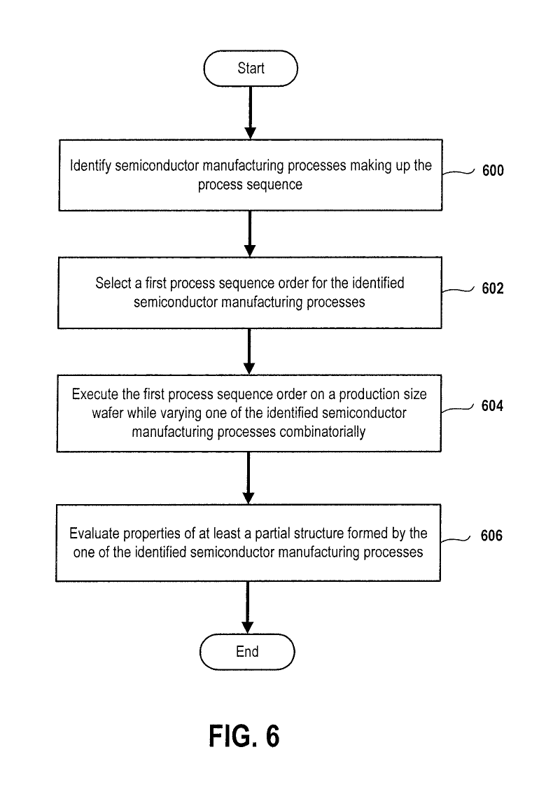

FIG. 6 is a flow chart diagram illustrating the method operations for selecting an optimized process sequence for a semiconductor manufacturing process in accordance with one embodiment of the invention. The method initiates with operation 600 where semiconductor manufacturing processes making up a process sequence are identified. One skilled in the art will appreciate that any suitable semiconductor manufacturing process which requires a sequence of operations may be evaluated through the method described herein. Of course, the sequence operations may be based on dry, wet or any other possible manufacturing process, or some combination of these. The method then advances to operation 602 where a first process sequence order for the semiconductor manufacturing process is selected. As the process sequence for the manufacturing process is made up of a number of operations, variation in the order of these operations is possible. Thus, in operation 602 one of the variations of the sequence order is selected. As mentioned with reference to FIG. 1, the variation may be applied to different regions or to different steps with a process sequence, but within a region the processing is substantially uniform to create structures, or partial structures, within the region that can be compared with each other for statistical validity of the process sequence being tested. These structures can likewise be compared to structures of other regions for determining optimum materials, unit processes, or process sequences without being concerned with non-uniformity between regions causing the effect.

The method then advances to operation 604 where the first process sequence order is executed while varying one of the identified semiconductor manufacturing processes combinatorially It should be noted that the use of a production size wafer is optional here as a coupon or portion of a wafer may be used. Here, as illustrated in FIG. 2, one of the operations making up the sequence is combinatorially varied in order to provide information to narrow a number of candidates for the manufacturing process. The operation being combinatorially varied may be evaluated through the primary, secondary, and tertiary screening scheme described herein. As illustrated in FIG. 4, the primary screening may focus more on materials used during the processing. One skilled in the art should appreciate that the sequence order within the combinatorial regions may be varied across the wafer to provide further information to evaluate the materials, processes, and process sequences.

The method of FIG. 6 then advances to operation 606 where the properties of at least a partial structure formed by one of the identified semiconductor manufacturing processes are evaluated. The results from this evaluation may be used to define further process sequences or select process sequences, or sequence orders or combinations of materials to further test. The materials identified through operation 604 are used in the further screening. The process described in FIG. 6 is iterative and the results from various stages of screening enable the user to find the optimal global solution.

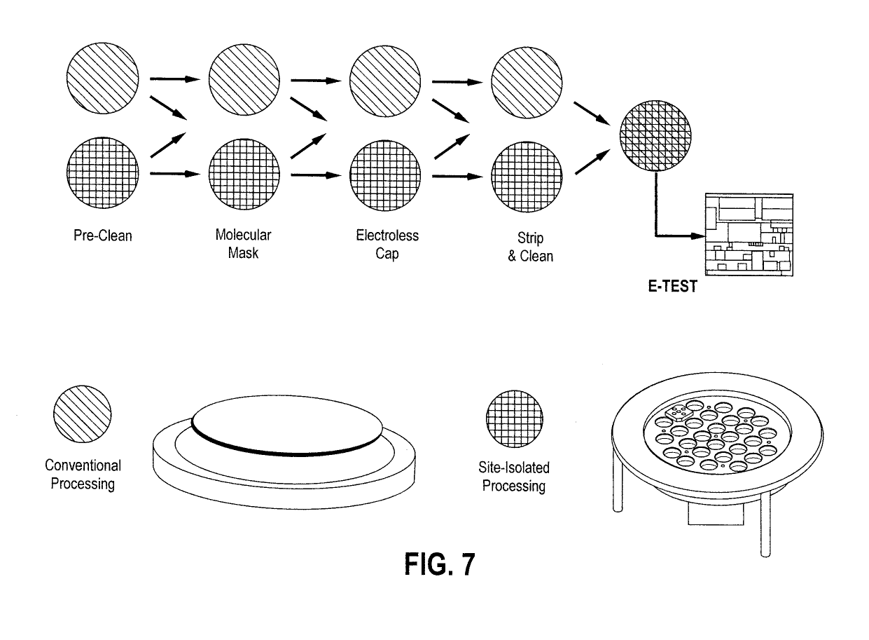

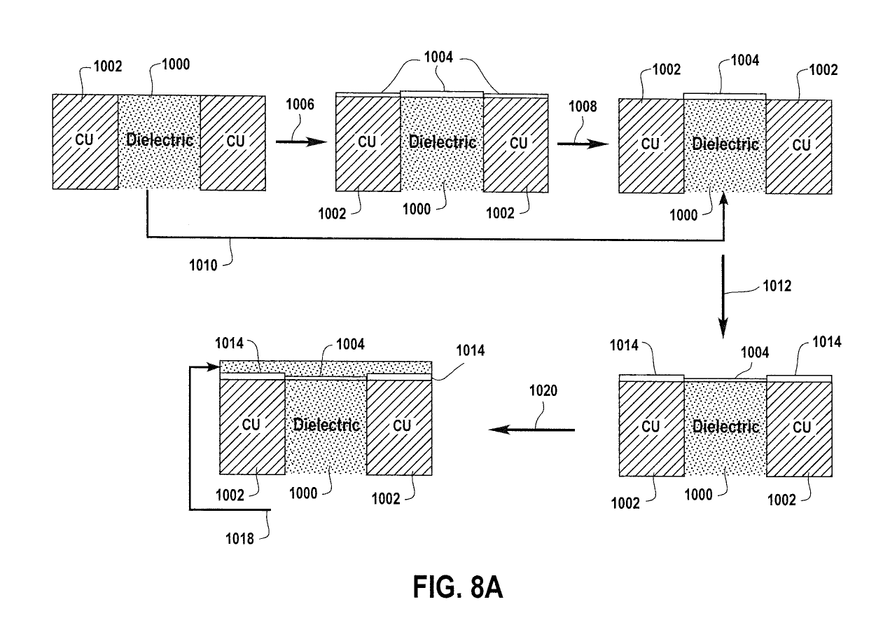

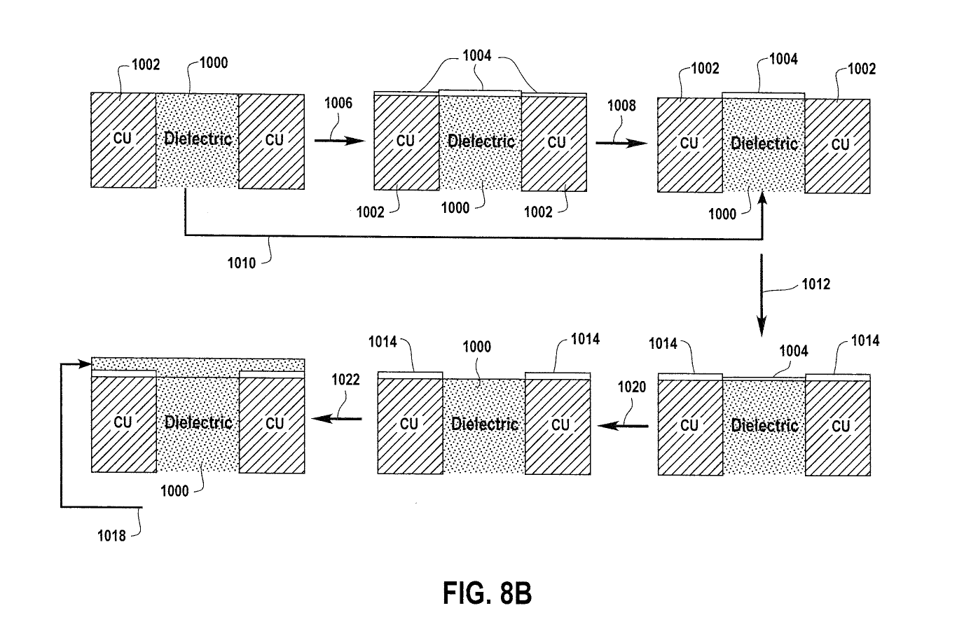

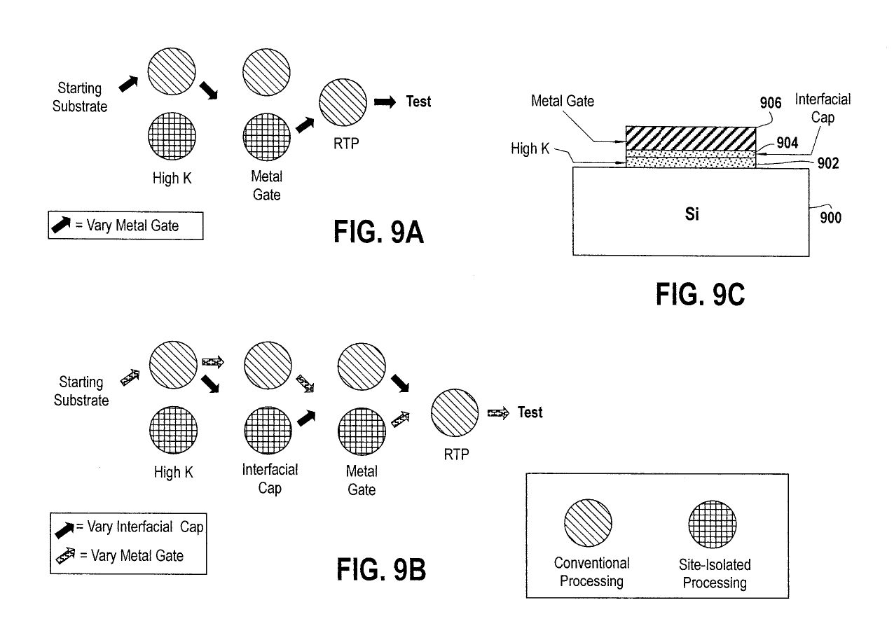

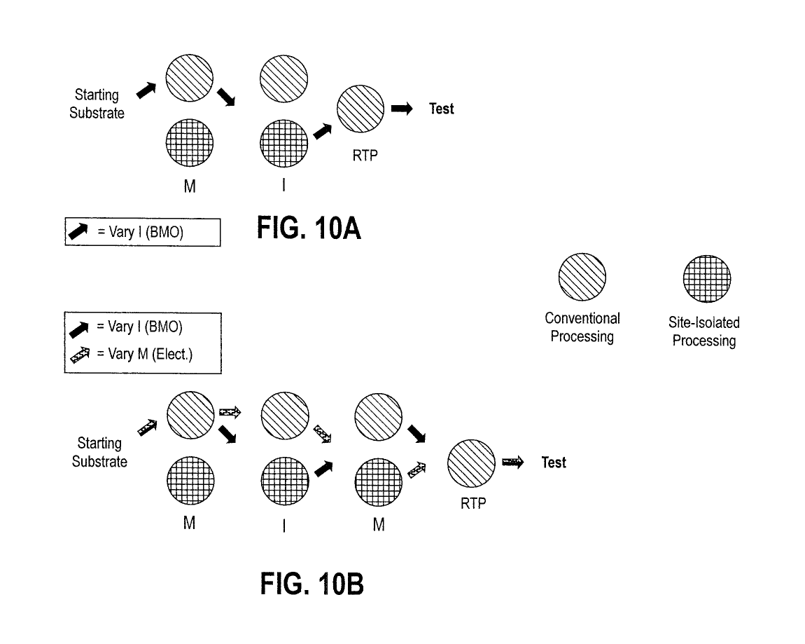

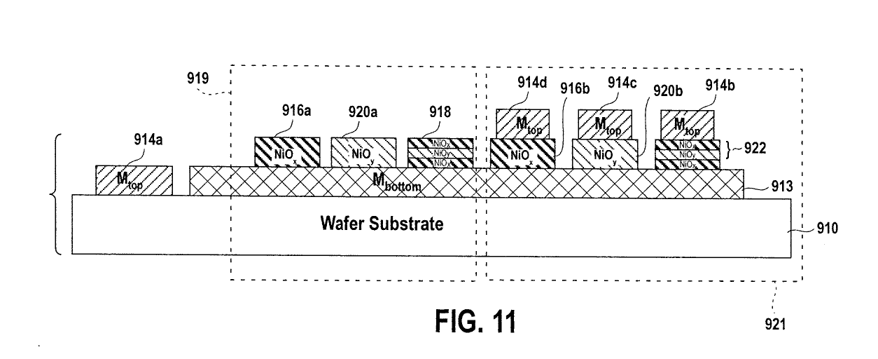

FIGS. 7-11 are illustrative of the screening techniques described herein being applied to particular semiconductor manufacturing process flows. FIGS. 7, 8A, and 8B are directed to the evaluation of the process sequence integration for an electroless copper capping application. FIGS. 9A-9C are directed to the evaluation of the process sequence integration for a metal gate application. FIGS. 10A, 10B, and 11 are directed to the evaluation of the process sequence integration for a metal-insulator-metal application for a memory device.

FIGS. 7, 8A, and 8B illustrate a combinatorial processing approach to discovering new materials, unit processes and/or process sequence integration schemes to address electromigration issues by facilitating formation of a capping layer on electrically conductive portions of a region separated by a dielectric portion in accordance with one embodiment of the invention. The site-isolated multi-processing methods and systems described herein can be used to examine variations in one or more of the unit process steps listed below, sequencing of the processes, and combinations thereof, such that two or more regions of a substrate effectively receive a different process or sequence of processes, or processing history.

FIG. 7 is a simplified schematic diagram illustrating a specific example for integrating a combinatorial process with conventional processing in order to evaluate process sequence integration that includes site isolated processing in accordance with one embodiment of the invention. One example of the processing sequence under the embodiments of FIG. 7 includes processing the substrate using a site isolated pre-clean processing operation initially. The site isolated pre-clean processes may be used to evaluate between multiple cleaning chemistries, different dilutions of the chemistries, different residence times on the substrate surface, an order of application of different cleaning chemistries, etc. The substrate is then processed using a conventional molecular mask processing, a conventional electroless cap process operation, and a conventional strip and clean operation. Conventional processes, as used herein, refer to substantially uniform processing of a monolithic substrate as compared to combinatorial processing of regions.

Thereafter electrical testing (E-test) is performed. From the results of the E-test, which include impact to line resistance, impact to capacitance, and impact to line-to-line leakage, the pre-clean processes associated with the most favorable results are selected and further combinatorial process sequence integration is executed. For example, a relatively small subset of the pre-clean possibilities is selected and set as a conventional process. Then, the electroless cap process may be combinatorially evaluated, where the pre-clean, molecular mask and the strip and clean operations are performed using a conventional process. The evaluation of the electroless cap process includes evaluation of different reducing agents, complexing agents, buffers, surfactants, temperatures for the process, pH ranges, cobalt and/or other source metal and/or metal alloy concentrations, deposition times, etc.

The evaluation of each of these processes combinatorially may include a methodical approach, which includes the primary, secondary, and tertiary evaluations as mentioned with reference to FIGS. 3 and 4. Each of the individual processes making up the process sequence may be evaluated in this manner so that a global optimum, that considers the process interactions between the individual processes, is identified. While the embodiments described above consider performing one process operation combinatorially in the process sequence, this is not meant to be limiting. It should be appreciated that the combinatorial process can be incorporated into any of the process operations, e.g., where multiple operations are performed combinatorially in order to more efficiently evaluate different materials processes and process sequences.

FIG. 8A illustrates an exemplary workflow of the screening process described herein as applied to a copper capping layer in accordance with one embodiment of the invention. A region of a substrate includes a dielectric portion (such as SiO2, SiCOH, SiOC, SiCO, SiC, SiCN, etc.) 1000 and an electrically conductive portion (such as copper or copper oxide) 1002. After cleaning, a masking layer 1004 is formed at least on the dielectric portion 1000 of the region. In one embodiment, the region is processed in such a way that the masking layer 1004 forms on all portions of the region (shown by step 1006), but is easily removable from the electrically conductive portions 1002 of the region (shown by step 1008) resulting in masking layer 1004 on only the dielectric portion 1000 of the region. In another embodiment, the region is processed so that the masking layer 1004 is selective only to the dielectric portion 1000 of the region and forms a layer only on the dielectric portion 1000 of the region as shown by operation 1010. An electroless cobalt (Co) alloy deposition process 1012 then deposits a capping layer (such as CoW, CoWP, CoWB, CoB, CoBP, CoWBP, Co containing alloys, etc.) 1014 on the electrically conductive portions 1002 of the region wherein the masking layer 1004 inhibits capping layer 1014 formation over the dielectric portion 1000 of the region. In one embodiment, after formation of the masking layer 1004, a dielectric barrier layer 1018 (such as, silicon nitride, silicon carbide, silicon carbon nitride, etc.) is subsequently formed on top of the capping layer 1014 and masking layer 1004.

In another embodiment, as illustrated in FIG. 8B, after formation of the capping layer 1014 by the electroless alloy deposition 1012, the masking layer 1004 is subsequently removed 1020 from the dielectric portion 1000 thereby removing any unwanted capping layer residue which may otherwise have formed over the dielectric portion 1000. In this fashion, the effective selectivity of the capping layer formation on the conductive portion(s) 1002 relative to the dielectric portion(s) 1000 is improved. In one embodiment, after removal of the sacrificial masking layer 1004, a dielectric barrier layer 1018 (such as silicon nitride, silicon carbide, silicon carbon nitride, etc.) is subsequently formed 1022 on top of the capping layer 1014 and dielectric portion(s) 1000.

Thus, the unit process steps involved with the above-reference approach include for example:

1. delivering cleaning solution(s) to remove organic and metallic contamination from exposed dielectric surfaces;

2. delivering cleaning and/or reducing solution(s) to remove the copper oxide and contamination from exposed copper surfaces;

3. delivering wetting, functionalization, and/or organic coating agents to form a masking layer on the dielectric portions of the substrate;

4. delivering and effecting a multicomponent (including but not limited to Co containing agents, transition metal containing agents, reducing agents, pH adjusters, surfactants, wetting agents, DI water, DMAB, TMAH, etc.) plating chemistry for electroless plating of a Co containing film;

5. delivering post plate etching and/or cleaning solution(s) to remove the sacrificial masking layer whereby excess plating material, such as Co particulates and other unwanted contamination which would otherwise have formed over the dielectric region(s) are removed through the removal of the masking layer

6. delivering post cleaning solution(s) to remove contamination and/or excess plating material, such as Co particulates from the capping layer;

7. rinsing the region; and

8. drying the region.

The site-isolated multiprocessing apparatus described above can be used to examine variations of each of the unit processes listed above, sequencing of the processes, and combinations thereof such that each region of die effectively receives a different process or processing history. Through the embodiments described herein, any of the processes, process sequence or the materials used in the process may be modified between regions of the substrate to evaluate the process interactions, as well as materials.

This following example illustrates a combinatorial processing approach to discovering new materials/processes/process sequence integration schemes to address the sealing of porous low-k dielectrics used in damascene (single or dual) copper interconnect formation. Porous low-k dielectrics are susceptible to precursor penetration during barrier layer formation such as in atomic layer deposition (ALD) processes which can lead to poisoning of the low-k dielectric, the inability to form a continuous barrier layer, the inability to form a thin and continuous barrier layer, etc., all of which can subsequently lead to poor device performance. Porous low-k dielectrics also typically exhibit poor (i.e. weaker) adhesion characteristics to barrier layers (e.g. Ta, TaₓC_{y}, TaₓN_{y}, TaₓC_{y}N_{z}, W, WₓC_{y}, WₓN_{y}, WₓC_{y}N_{z}, Ru, etc.) as compared to standard dielectrics (e.g. SiO2, FSG, etc.) which can lead to poor device reliability. It is desirable to be able to seal the exposed pores of porous low-k dielectrics and/or improve the adhesion properties of porous low-k dielectrics to barrier layers used in copper interconnect formation.

The unit process steps (involved with the above-referenced approach) for sealing of porous low-k dielectrics used in copper interconnect formation include for example:

1. delivering cleaning solution(s) to remove organic and metallic contamination from exposed dielectric surfaces;

2. delivering cleaning and/or reducing solution(s) to remove the copper oxide and contamination from exposed copper surfaces;

3. delivering wetting, functionalization, and/or coating agents selectively from a molecularly self-assembled layer(s) on the exposed dielectric surfaces so as to substantially fill and/or seal the exposed pores of the exposed dielectric surfaces;

4. delivering cleaning solution(s) to remove contamination and/or residue (resulting from step 3) from exposed copper surfaces;

5. rinsing the region;

6. drying the region; and

7. performing post-processing treatment, e.g., thermal, UV, IR, etc.

FIGS. 9A-9C illustrates the application of the screening process to a process sequence for a gate stack configuration in accordance with one embodiment of the invention. As the use of high dielectric constant (referred to as High K) materials have become a viable alternative in the manufacture of semiconductor devices, especially for use as the gate oxide, there has been a great deal of interest in incorporating these materials into the process sequence for the manufacturing of semiconductor devices. However, in order to address mobility degradation and/or threshold voltage shifts that have been observed, an interfacial cap layer may be disposed between the gate and the gate oxide to alleviate such degradation.

As illustrated in FIG. 9C, silicon substrate 900 has High K gate oxide 902, interfacial cap 904 and gate 906 disposed thereon. One approach to incorporate the screening technique discussed above is to fix the High K material being disposed over the substrate in FIG. 9A. In one embodiment, the High K material may be hafnium silicate or hafnium oxide. Fixing the High K component refers to performing this operation in a conventional manner (e.g., via atomic layer deposition). The process sequence for forming the metal gate is then varied combinatorially. Various metals can be used initially, such as tantalum silicon nitride, tantalum nitride, ruthenium, titanium nitride, rhenium, platinum, etc. The HPC system described in FIG. 5A can be used to effect such site isolated processing in one embodiment. The resulting substrate is processed through a rapid thermal processing (RTP) step and the resulting structure of the metal over the insulator over the semiconductor substrate is then tested. Such tests include thermal stability, crystallization, delamination, capacitance-voltage, flat-band voltage, effective work function extrapolation, etc.

It may be determined that the use of a metal alone with the High K gate is not compatible as defects are introduced into the structure as evidenced by testing results (e.g., fermi level pinning). Thus, as illustrated in FIG. 9B, a different process sequence is evaluated where an interfacial cap is disposed between the gate and the gate oxide. In one embodiment, the High K processing and the metal gate processing are fixed, while the interfacial cap processing is varied combinatorially. The substrate is annealed through RTP and the resulting structure are tested to identify optimum materials, unit processes and process sequences with an interfacial cap introduced between the High K material and the gate material. Examples of potential interfacial cap layers include lanthanum, magnesium, scandium, hafnium fluoride, lanthanum fluoride, etc. The RTP processing may include rapid thermal oxidation.

FIGS. 10A and 10B illustrate an exemplary screening technique for evaluating a metal-insulator-metal (MIM) structure for a memory device element in accordance with one embodiment of the invention. The memory device element in this example is a resistive change memory element that changes between a high resistive state and a low resistive state. The metal for this example is a conductive element (e.g. W, Ta, Ni, Pt, Tr, Ru, etc.) or a conductive compound (e.g. TiN, TaN, WN, RuO₂, IrO₂, etc.) and forms the electrodes for the MIM structure. The insulator in this example is a transition metal oxide, such as titanium oxide, niobium oxide, zirconium oxide, hafnium oxide, tantalum oxide, or nickel oxide. The insulator is also referred to as a binary metal oxide or BMO in this example.

An optimum process sequence for this example was developed with the screening approach described herein. FIG. 10A illustrates a starting substrate and then a metal electrode M (e.g., TiN) is initially deposited uniformly over the substrate, i.e., through a conventional manufacturing process (e.g. physical vapor deposition or sputtering). Then, site isolated processing (e.g., using HPC system described in FIG. 5A) is used to deposit (e.g. via physical vapor deposition) the insulator layer in regions of the substrate having the metal electrode deposited thereon. Some items that may be varied between the region include the partial pressure of the oxygen, gas flow, power levels for the deposition, substrate temperature, type of stack (graded or super stack), gas species, chamber pressure, thickness of the material deposited, etc. The resulting substrate is post processed through RTP and then tested. Thus, the substrate has a metal under layer and the oxide is varied and then the substrate is annealed. The testing includes adhesion properties of the layers, resistance testing, dewetting, phase/crystallinity, and composition. Based on the testing a certain subset (e.g., combinations which show poor adhesion, dewetting, or have too low a film resistance, etc.) of the combinations are eliminated.

Then, with this reduced subset, the effect of putting another electrode on top of the M-I structure is evaluated as depicted by FIG. 10B. Here, the bottom electrode and the insulator processes are fixed and the top electrode is varied. The resulting structures are annealed and tested as described above. The testing here may include current/voltage (I/V) testing for resistance switching (e.g. no switching, mono-stable switching, bi-stable switching, etc.) since the MIM stack has been constructed. As explained above, the testing is becoming more sophisticated as the screening process proceeds to define an optimal process sequence. The screening process determined an optimal metal oxide and corresponding unit processes in FIG. 10A, and then incorporated the optimal results to determine the process interaction with a top electrode as described with reference to FIG. 10B.

FIG. 11 illustrates a simplified cross sectional view of a substrate that has structures defined from combinatorial processing sequences for screening purposes in accordance with one embodiment of the invention. Substrate 910 has a bottom electrode 912 disposed thereon. Bottom electrode 912 may be a metal layer having one of the compositions listed for bottom electrode 912 in FIG. 11. However, any conductive material may be deposited for bottom electrode 912. In addition, top electrode 914a is defined over substrate 910. In one embodiment, the depositions of bottom electrode 912 and top electrode 914a can be considered primary screening where a number of different compositions for the top and bottom electrodes may be distributed over a surface of substrate 910 for subsequent testing. It should be noted that top electrode 914a is isolated from bottom electrode 912, while being on the same layer. As discussed above with reference to FIGS. 2A-2C, top electrode 914a and bottom electrode 912 may be adjacent to each other in another embodiment and the desired testing can still be executed. Defined over electrode 912 are nickel oxide insulators 916a and 920a, which have different oxygen compositions. Super stack 918 is another insulator defined over bottom electrode 912. Portion 919 of FIG. 11 represents structures that correspond to the output of FIG. 10A. That is, the metal-insulator pathway where the insulator is combinatorially varied in FIG. 10A would yield structures of portion 919 of FIG. 11. These structures can then be tested as described above and then additional structures are built such as the MIM structures defined in portion 921. The MIM structures of portion 921 have top electrodes 914b, 914c, and 914d disposed over insulators 922, 920b, and 916b, respectively. As discussed above with regard to FIG. 10B, the two metal deposition processes are fixed, while the insulators are varied combinatorially to yield the structures within portion 921 of FIG. 11. Eventually, a steering element, such as a diode, is added to make a true device to perform tertiary screening where more sophisticated electrical testing of the device is possible.

Still referring to FIG. 11, on the top surface of substrate 910 is a bottom and top electrode, which defines a variation on the top surface of the substrate. Similarly within potion 919 the insulator is varied without a top electrode, and within portion 921 the insulator is varied between the top and bottom electrodes. While the embodiments provide for this variation, the various layers, e.g., top electrodes 914c and 914d and/or insulators 916a, 916b, 920a, 920b, 922 and 918 are individually uniform or consistent within a region similar to a commercial semiconductor processing operation and as required across regions so the variation being tested is the known cause of the results. Thus, any differences in the testing of the insulator would not be due to variation in the formation of equivalently formed layers or structures. Furthermore, as the screening progresses from primary to tertiary screening, the processes are further defining commercial structures and the associated critical manufacturing parameters.

In summary, the embodiments described above enable rapid and efficient screening of materials, unit processes, and process sequences for semiconductor manufacturing operations. As illustrated in FIGS. 7-11, the combinatorial process sequencing takes a substrate out of the conventional process flow, introduces variation of structures or devices on a substrate in an unconventional manner, i.e., combinatorially. However, actual structures or devices are formed for analysis. That is, the layer, device, trench, via, etc., is the same as a layer device trench, via etc. defined through a conventional process. While the embodiments described above provide specific examples, these examples are illustrative and not meant to be limiting. The screening process described herein can be incorporated with any semiconductor manufacturing operation or other associated technology, such as process operations for flat panel displays, optoelectronics devices, data storage devices, magneto electronic devices, magneto optic devices, packaged devices, and the like.

The site-isolated multiprocessing methods and systems described in the present invention can be used to examine variations in one or more of the unit process steps listed above, sequencing of the processes, and combinations thereof, such that two or more regions of a substrate effectively receive a different process or sequence of processes, or processing history. The above examples are provided for illustrative purposes and not meant to be limiting. The embodiments described herein may be applied to any process sequence to optimize the process sequence, as well as the materials, processes, and processing conditions utilized in the manufacture of a semiconductor device where there exist multiple options for the materials, processes, processing conditions, and process sequences.

The present invention provides greatly improved methods and apparatus for the differential processing of regions on a single substrate. It is to be understood that the above description is intended to be illustrative and not restrictive. Many embodiments and variations of the invention will become apparent to those of skill in the art upon review of this disclosure. Merely by way of example a wide variety of process times, process temperatures and other process conditions may be utilized, as well as a different ordering of certain processing steps. The scope of the invention should, therefore, be determined not with reference to the above description, but instead should be determined with reference to the appended claims along with the full scope of equivalents to which such claims are entitled.

The explanations and illustrations presented herein are intended to acquaint others skilled in the art with the invention, its principles, and its practical application. Those skilled in the art may adapt and apply the invention in its numerous forms, as may be best suited to the requirements of a particular use. Accordingly, the specific embodiments of the present invention as set forth are not intended as being exhaustive or limiting of the invention.

The embodiments described above provide methods and apparatus for the parallel or rapid serial synthesis, processing and analysis of novel materials having useful properties identified for semiconductor manufacturing processes. Any materials found to possess useful properties can then subsequently be prepared on a larger scale and evaluated in actual processing conditions. These materials can be evaluated along with reaction or processing parameters through the methods described above. In turn, the feedback from the varying of the parameters provides for process optimization. Some reaction parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, etc. In addition, the methods described above enable the processing and testing of more than one material, more than one processing condition, more than one sequence of processing conditions, more than one process sequence integration flow, and combinations thereof, on a single substrate without the need of consuming multiple substrates per material, processing condition, sequence of operations and processes or any of the combinations thereof. This greatly improves the speed as well as reduces the costs associated with the discovery and optimization of semiconductor manufacturing operations.

Moreover, the embodiments described herein are directed towards delivering precise amounts of material under precise processing conditions at specific locations of a substrate in order to simulate conventional manufacturing processing operations. As mentioned above, within a region the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes and process sequences may vary. It should be noted that the discrete steps of uniform processing is enabled through the HPC systems described herein.

Any of the operations described herein that form part of the invention are useful machine operations. The invention also relates to a device or an apparatus for performing these operations. The apparatus can be specially constructed for the required purpose, or the apparatus can be a general-purpose computer selectively activated or configured by a computer program stored in the computer. In particular, various general-purpose machines can be used with computer programs written in accordance with the teachings herein, or it may be more convenient to construct a more specialized apparatus to perform the required operations.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims. In the claims, elements and/or steps do not imply any particular order of operation, unless explicitly stated in the claims.

What is claimed is:

1. A method for evaluating materials, unit processes, and process sequences for manufacturing a device, comprising:
processing regions on a first substrate in a combinatorial manner by varying one of materials, unit processes or process sequences;
testing the processed regions on the first substrate;
processing regions on a second substrate in a combinatorial manner by varying one of materials, unit processes or process sequences based on the results of the tests of the processed regions on the first substrate; and
testing the processed regions on the second substrate.

2. The method of claim 1, further comprising;
processing regions on a third substrate in a combinatorial manner by varying one of materials, unit processes or process sequences and testing the processed regions on the third substrate.

3. The method of claim 1, wherein testing the processed regions on the first substrate yields materials properties results.

4. The method of claim 1, wherein the first substrate is a blanket wafer and the second substrate is a patterned wafer.

5. The method of claim 1, wherein the processing on the first substrate and the processing on the second substrate are performed in a same combinatorial process module.

6. The method of claim 1, wherein the processing on the first substrate and the processing on the second substrate are performed in different combinatorial process modules.

7. The method of claim 1, wherein the first and second substrates are patterned, wherein the pattern of the second substrate incorporates at least one structure from the pattern of the first substrate.

8. The method of claim 1, wherein one of a unit process or a process sequence is varied across multiple regions.

9. The method of claim 1, wherein regions on the second substrate are larger in size than regions on the first substrate.

10. The method of claim 1, wherein the processing forms structures on the regions of the second substrate that correlate to structures on a commercial semiconductor chip.

11. The method of claim 1, wherein structures on the second substrate are more closely tied to commercial device structures than structures on the first substrate and wherein testing the processed regions on the second substrate are based on critical parameters of a commercial device.

12. The method of claim 1, wherein the results from testing the processed regions on the second substrate are fed back to educate processing on the first substrate.

13. The method of claim 1, wherein processing is uniform within the regions.

14. The method of claim 1, wherein the regions on respective substrates overlap but a portion of each of the regions is substantially uniform.

15. The method of claim 1, wherein the processing of regions is uniform across respective different regions so that test results from the respective different regions result from the varying.

16. The method of claim 2, wherein electrical tests of formed structures on the third substrate determine whether the formed structures meet device parameters.

17. A method for evaluating materials, unit processes, and process sequences for a manufacturing operation, comprising:
processing regions on a first substrate in a combinatorial manner by varying materials of the manufacturing operation;
testing the processed regions on the first substrate;
processing regions on a second substrate in a combinatorial manner by varying unit processes of the manufacturing operation based on the results of the tests of the processed regions on the first substrate; and
testing the processed regions on the second substrate.

18. The method of claim 17, wherein the first substrate is a blanket substrate.

19. The method of claim 17, wherein the manufacturing operation is selected from a group of operations consisting of process operations for flat panel displays, optoelectronics devices, data storage devices, magneto electronic devices, magneto optic devices, and packaged devices.

20. A method for evaluating materials, unit processes, and process sequences for a manufacturing operation, comprising:
processing regions on a first substrate in a combinatorial manner by varying unit processes of the manufacturing operation;
testing the processed regions on the first substrate;
processing regions on a second substrate in a combinatorial manner by varying process sequences of the manufacturing operation based on the results of the tests of the processed regions on the first substrate; and
testing the processed regions on the second substrate.

21. The method of claim 20, wherein tests performed when testing the processed regions on the second substrate are more sophisticated relative to tests performed when testing the processed regions on the first substrate

22. The method of claim 20, further comprising:
forming a structure when processing regions on the first substrate; and
forming a structure when processing regions on the second substrate, wherein the structure formed when processing regions on the second substrate is more similar to a commercial structure than the structure formed when processing regions on the first substrate.

23. The method of claim 20, wherein materials selected for processing regions on the first substrate in a combinatorial manner result from a prior combinatorial screening utilizing one of a gradient or a site isolated combinatorial process.
